(19) United States
(12) Patent Application Publication
(10) Pub. No.: US 2015/0180493 A1
(43) Pub. Date: Jun. 25, 2015

(54) Capacitor Sensor Circuit with Rectifier and Integrator

(71) Applicants: Yu-Ren Liu, Hsinchu County (TW); Ping-Pao Cheng, Hsinchu County (TW)

(72) Inventors: Yu-Ren Liu, Hsinchu County (TW); Ping-Pao Cheng, Hsinchu County (TW)

(21) Appl. No.: 14/139,848

(22) Filed: Dec. 23, 2013

(51) Int. Cl. H03M 1/00; H02M 3/06; H03M 1/12; G01R 27/26; G01B 7/00

(52) U.S. Cl. CPC H03M 1/002; G01R 27/2605; G01B 7/003; H03M 1/12; H02M 3/06; G01B 2210/58

(57) ABSTRACT

A capacitor sensor circuit may be used in application such as touch screens. The capacitor sensor circuit includes a transimpedance amplifier, a filter module, a rectifier, an integrator and an analog to digital converter. Since a transmission signal fed into the capacitor sensor circuit has been preprocessed through the rectifier and the integrator, the analog to digital converter to be used can be a low speed analog to digital converter that has lower power consumption and a lower cost of manufacturing compared to a high speed analog to digital converter.

### BACKGROUND OF THE INVENTION

1. Field of the Invention

The present invention discloses a capacitor sensor circuit, and more particularly, a capacitor sensor circuit with a rectifier and an integrator to be used for applications that require human machine interface.

2. Description of the Prior Art

Touch panels are widely used by mobile devices such as smart pads and smart phones. Use of capacitive sensing in touch panels to implement human to machine interfaces is becoming a common practice.

According to prior art, integrated circuits designed to implement capacitance sensing for human to machine interface applications require use of high speed analog to digital converters. The high speed analog to digital converters are used to convert the analog signal from a capacitor sensor to a digital signal. The digital signal will then pass through a mixer circuit to implement demodulation of the digital signal.

The manufacturing of the prior art is at high cost since the high speed analog to digital converters require a complicated circuitry. Therefore, the die area used for the high speed analog to digital converters is relatively bigger. Aside from manufacturing cost, the high speed analog to digital converters also require high power consumption as compared to a low speed analog to digital converters. The performance of the high speed analog to digital converters are also largely affected by process making the high speed analog to digital converters harder to manufacture due to precision requirement. Aside from the high speed analog to digital converter, the prior art also require the use of the mixer circuit which usually includes a multiplier. Therefore, the use of the mixer circuitry will not be suitable for producing low cost integrated circuits.

### SUMMARY OF THE INVENTION

An embodiment of the present invention discloses a capacitor sensor circuit. The capacitor sensor circuit comprises a transimpedance amplifier, comprising an operational amplifier, having a negative input terminal coupled to a receiver node, a positive input terminal coupled to a reference voltage, and an output terminal; a capacitor, having a first terminal coupled to the receiver node and a second terminal coupled to the output terminal of the operational amplifier; a filter module, having an input terminal coupled to the output terminal of the operational amplifier and an output terminal; a rectifier, having an input terminal coupled to the output terminal of the filter module and an output terminal; an integrator, having an input terminal coupled to the output terminal of the rectifier and an output terminal; and an analog to digital converter, having an input terminal coupled to the output terminal of the integrator and an output terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a capacitor sensor circuit according to an embodiment of the present invention.

FIG. 2 illustrates a schematic diagram of the capacitor sensor according to the capacitor sensor circuit shown in FIG. 1

FIG. 3 illustrates a schematic diagram of the transimpedance amplifier according to the capacitor sensor circuit shown in FIG. 1

FIG. 4 illustrates a schematic diagram of the rectifier according to the capacitor sensor circuit shown in FIG. 1.

FIG. 5 illustrates a schematic diagram of the first embodiment of the integrator according to the capacitor sensor circuit shown in FIG. 1.

FIG. 6 illustrates a schematic diagram of the second embodiment of the integrator according to the capacitor sensor circuit shown in FIG. 1.

FIG. 7 illustrates a schematic diagram of the third embodiment of the integrator according to the capacitor sensor circuit shown in FIG. 1.

### DETAILED DESCRIPTION

The present invention discloses an embodiment of a capacitor sensor circuit with a rectifier and an integrator. The embodiment of the present invention may be applied to touch panel control of any mobile device including smart pads, and smart phones.

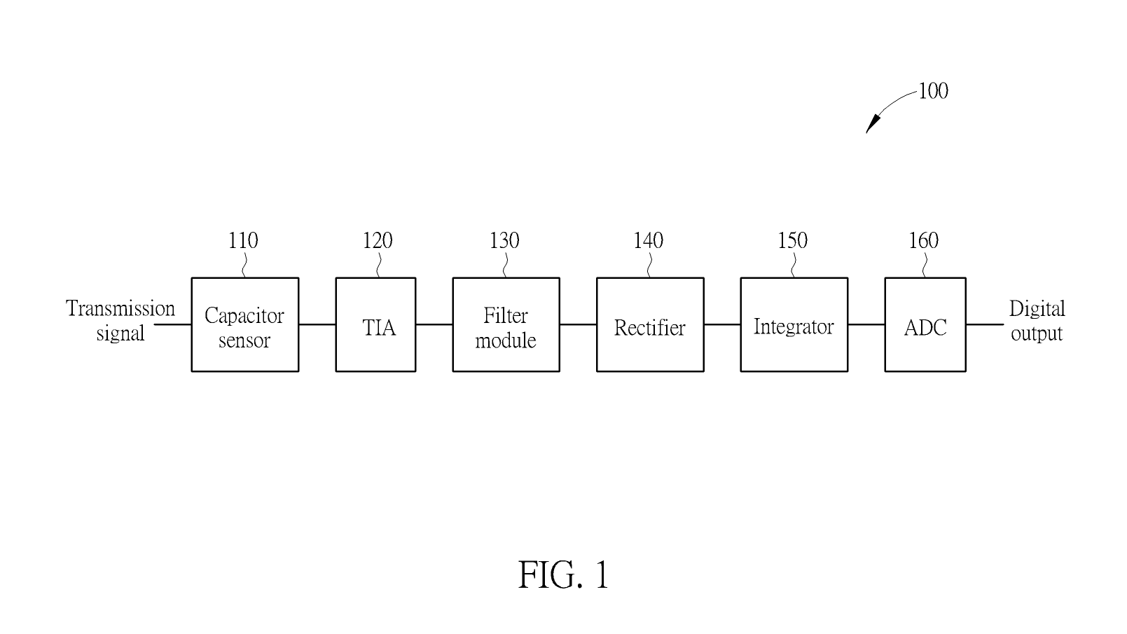

Please refer to FIG. 1. FIG. 1 illustrates a capacitor sensor circuit 100 according to an embodiment of the present invention. The capacitor sensor circuit 100 comprises a capacitor sensor 110, a transimpedance amplifier (TIA) 120, a filter module 130, a rectifier 140, an integrator 150 and an analog to digital converter (ADC) 160. A transmitter node of the capacitor sensor 110 is coupled to a signal source generating a transmission signal. An input terminal of the transimpedance amplifier 120 is coupled to a receiver node of capacitor sensor 110. An input terminal of the filter module 130 is coupled to an output terminal of the transimpedance amplifier 120. An input terminal of the rectifier 140 is coupled to an output terminal of the filter module 130. An input terminal of the integrator 150 is coupled to an output terminal of the rectifier 140. An input terminal of the analog to digital converter 160 is coupled to an output terminal of integrator 150 and a second terminal of the analog to digital converter 160 outputs a digital output of the capacitor sensor circuit 100.

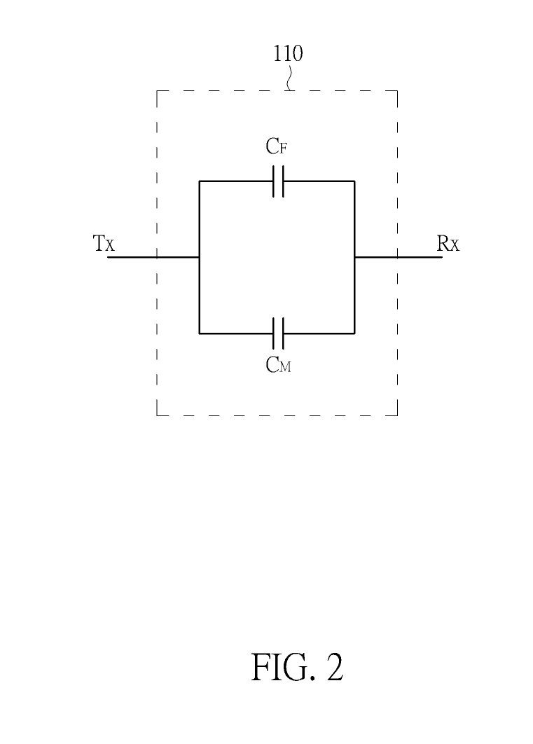

Please refer to FIG. 2. FIG. 2 illustrates a schematic diagram of the capacitor sensor 110 according to the capacitor sensor circuit 100 shown in FIG. 1. The capacitor sensor 110 comprises of a finger capacitor C_{F} and a mutual capacitor C_{M}. The finger capacitor C_{F} and the mutual capacitor C_{M} are coupled in parallel to each other. First terminals of the finger capacitor C_{F} and the mutual capacitor C_{M} are coupled to the transmitter node Tx and second terminals of the finger capacitor C_{F} and the mutual capacitor C_{M} are coupled to the receiver node Rx. An equivalent capacitance of the finger capacitor C_{F} and the mutual capacitor C_{M} is measured and used by the transimpedance amplifier 120 for processing of the transmission signal when a finger or any conductive material is sensed on the finger capacitor C_{F}.

The capacitor sensor 110 work based on capacitive coupling having to take human body capacitance as an input. The capacitor sensor 110 can detect anything that is conductive or has a dielectric difference from that of air. The equivalent capacitance of the capacitor sensor 110 is measured indirectly by using the equivalent capacitance of the capacitor sensor 110 to vary the level of coupling or attenuation of an alternating current signal, i.e., the transmission signal. When presence of a finger is detected on the finger capacitor C_{F} of the capacitor sensor 110, a change in the equivalent capacitance of the capacitor sensor 110 shall occur. On a touch panel that has a plurality of capacitor sensors 110, if a change in the equivalent capacitance of at least one capacitor sensor 110 occurs, the at least one capacitor sensor 110 may correspond to a coordinate on the touch panel that has been selected by a user. The coordinate selected may be a select button of a user interface shown on the touch panel which may correspond to a command to be executed by a mobile device. The change in the equivalent capacitance of the at least one capacitor sensor 110 shall generate a signal as an indicator to execute the corresponding command.

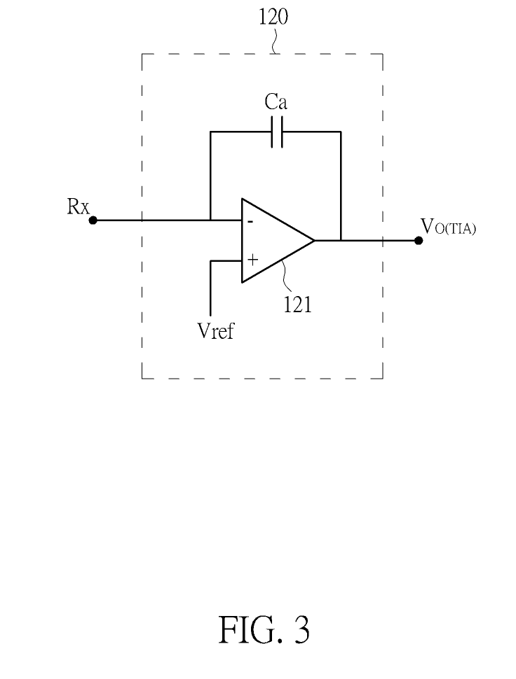

Please refer to FIG. 3. FIG. 3 illustrates a schematic diagram of the transimpedance amplifier 120 according to the capacitor sensor circuit 100 shown in FIG. 1. The transimpedance amplifier 120 comprises an operational amplifier 121, and a capacitor Ca. The capacitor Ca having a first terminal coupled to a negative input terminal of the operational amplifier 121 and a second terminal coupled to an output terminal of the operational amplifier 121. The output terminal of the operational amplifier 121 is coupled to the output terminal V_{O(TIA)} of the transimpedance amplifier 120. A positive input terminal of the operational amplifier 121 is coupled to a reference voltage V_{REF}. The negative input terminal of the operational amplifier 121 is coupled to the receiver node Rx. The transimpedance amplifier 120 uses the capacitor Ca to convert an injected signal into an output signal with voltage value relative to the reference voltage V_{REF}. The injected signal of the transimpedance amplifier 120 is the transmission signal from the receiver node Rx. The output signal of the transimpedance amplifier 120 is a signal equivalent to the transmission signal having amplitude proportional to the equivalent capacitance of the capacitor sensor 110 and the reference voltage V_{REF}. Note that the transimpedance amplifier 120 may also include a reset switch having a first terminal coupled to the negative input terminal of the operational amplifier 121, a second terminal coupled to the output terminal of the operational amplifier 121 and a control terminal receiving a reset signal for additional stability.

The filter module 130 according to the capacitor sensor circuit 100 shown in FIG. 1 has an input terminal coupled to the output terminal V_{O(TIA)} of the transimpedance amplifier 120 and an output terminal coupled to the input terminal V_{IN(REC)} of the rectifier 140. The filter module 130 comprises of two different filter circuits. A first filter circuit may be a low pass filter or a band pass filter. A second filter circuit may be a switch capacitor band pass filter or a switch capacitor high pass filter. The second filter circuit may also be a sample and hold circuit. A first filter circuit combination of the filter module 130 includes the low pass filter and the switch capacitor band pass filter. A second filter circuit combination of the filter module 130 includes the low pass filter and the sample and hold circuit. A third filter circuit combination of the filter module 130 includes the low pass filter and the switch capacitor high pass filter. A fourth filter circuit combination of the filter module 130 includes the band pass filter and the sample and hold circuit. The first filter circuit combination, the second filter circuit combination, the third filter circuit combination and the fourth filter circuit combination each function as a band pass filter.

For the first filter circuit combination, the input terminal of the filter module 130 is coupled to an input terminal of the low pass filter. An output terminal of the low pass filter is coupled to an input terminal of the switch capacitor band pass filter. And an output terminal of the switch capacitor band pass filter is coupled to the output terminal of the filter module 130. In another embodiment of the first filter circuit combination, the input terminal of the filter module 130 is coupled to an input terminal of the switch capacitor band pass filter. An output terminal of the switch capacitor band pass filter is coupled to an input terminal of the low pass filter. And an output terminal of the low pass filter is coupled to the output terminal of the filter module 130.

For the second filter circuit combination, the input terminal of the filter module 130 is coupled to the input terminal of the low pass filter. The output terminal of the low pass filter is coupled to an input terminal of the sample and hold circuit. And an output terminal of the sample and hold circuit is coupled to the output terminal of the filter module 130. In another embodiment of the second filter circuit combination, the input terminal of the filter module 130 is coupled to an input terminal of the sample and hold circuit. An output terminal of the sample and hold circuit is coupled to an input terminal of the low pass filter. And an output terminal of the low pass filter is coupled to the output terminal of the filter module 130.

For the third filter circuit combination, the input terminal of the filter module 130 is coupled to the input terminal of the low pass filter. The output terminal of the low pass filter is coupled to an input terminal of the switch capacitor high pass filter. And an output terminal of the switch capacitor high pass filter is coupled to the output terminal of the filter module 130. In another embodiment of the third filter circuit combination, the input terminal of the filter module 130 is coupled to an input terminal of the switch capacitor high pass filter. An output terminal of the switch capacitor high pass filter is coupled to an input terminal of the low pass filter. And an output terminal of the low pass filter is coupled to the output terminal of the filter module 130.

For the fourth filter circuit combination, the input terminal of the filter module 130 is coupled to an input terminal of the band pass filter. An output terminal of the band pass filter is coupled to an input terminal of the sample and hold circuit. And an output terminal of the sample and hold circuit is coupled to the output terminal of the filter module 130. In another embodiment of the fourth filter circuit combination, the input terminal of the filter module 130 is coupled to an input terminal of the sample and hold circuit. An output terminal of the sample and hold circuit is coupled to an input terminal of the band pass filter. And an output terminal of the band pass filter is coupled to the output terminal of the filter module 130.

The filter module 130 receives the output signal of the transimpedance amplifier 120 from the input terminal of the filter module 130 and converts the output signal of the transimpedance amplifier 120 to a discrete sinusoidal signal. The conversion of the output signal of the transimpedance amplifier 120 that is an analog signal to the discrete sinusoidal signal can be performed by the switch capacitor band pass filter, the switch capacitor high pass filter or the sample and hold circuit.

The sample and hold circuit is an analog device that samples the voltage of a continuously varying analog signal and holds the value of the continuously varying analog signal at a constant level for a specified minimum period of time. The sample and hold circuit will have a discrete signal as an output.

A switched capacitor filter is a type of filter that uses switched capacitors to emulate resistors. The switched capacitor filter moves charges in and out of capacitors when switches are opened and closed. The switched capacitor filter uses control signals that are not overlapping so as not to close all switches used simultaneously. The advantage of using the switched capacitor filter is the matching of similar devices makes implementation of relative high precision analog filters possible on integrated circuits. The switched capacitor filter will also have a discrete signal as an output.

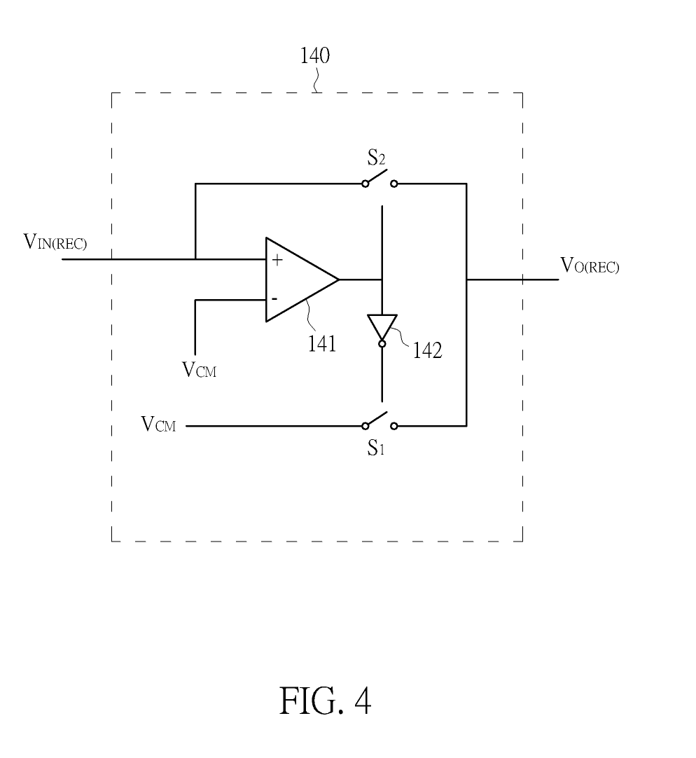

Please refer to FIG. 4. FIG. 4 illustrates a schematic diagram of the rectifier 140 according to the capacitor sensor circuit 100 shown in FIG. 1. The rectifier 140 comprises an operational amplifier 141, and inverter 142, a first switch S1 and a second switch S2. The positive input terminal of the operational amplifier 141 is coupled to the input terminal V_{IN(REC)} of the rectifier 140. The negative input terminal of the operational amplifier 141 is coupled to a common mode voltage V. The output terminal of the operational amplifier 141 is coupled to an input terminal of the inverter 142. An output terminal of the inverter 142 is coupled to a control terminal of the first switch S1. A first terminal of the first switch S1 is coupled to the common mode voltage V. A second terminal of the first switch S1 is coupled to the output terminal V_{O(REC)} of the rectifier 140. A control terminal of the second switch S2 is coupled to the output terminal of the operational amplifier 141. A first terminal of the second switch S2 is coupled to the positive input terminal of operational amplifier 141. A second terminal of the second switch S2 is coupled to the output terminal V_{O(REC)} of the rectifier 140. The discrete sinusoidal signal from the filter module 130 is inputted to the rectifier 140.

The rectifier 140 is used to convert a sinusoidal signal that periodically reverses in direction of polarity to a direct current signal which flows in only one direction of polarity. The present invention may use a single phase rectifier that may implement half wave rectification or full wave rectification. Half wave rectification takes the sinusoidal signal that is single phase as its input. Only the positive half of the sinusoidal signal is passed and the negative half is blocked. Or only the negative half of the sinusoidal signal is passed and the positive half is blocked. Full wave rectification takes the sinusoidal signal that is single phase as its input. Whole of the sinusoidal signal is converted to a waveform with positive constant polarity. Or whole of the sinusoidal signal is converted to a waveform with negative constant polarity. The sinusoidal signal is converted to a pulsating direct current signal and yields a higher average output voltage.

The rectifier 140 shown in FIG. 4 is a single phase half wave rectifier. The rectifier 140 takes the discrete sinusoidal signal as an input to the operational amplifier 141. Voltage value of the discrete sinusoidal signal is taken and compared to the common mode voltage V_{CM}. Result of comparison shall determine the output of the operational amplifier 141 and is used as a control signal for the first switch S1 and the second switch S2. If voltage value of the discrete sinusoidal signal is higher than the common mode voltage V_{CM}, the operational amplifier 141 shall output a logic high value. When the first switch S1 and the second switch S2 are positive trigger switches, logic high value from the operational amplifier 141 will turn on the second switch S2. Voltage value of the discrete sinusoidal signal shall then be taken as an output value of the rectifier 140. If voltage value of the discrete sinusoidal signal is lower than the common mode voltage V_{CM}, the operational amplifier 141 shall output a logic low value. When the first switch S1 and the second switch S2 are positive trigger switches, logic low value from the operational amplifier 141 will turn on the first switch S1. The common mode voltage V_{CM} shall then be taken as an output value of the rectifier 140.

If the rectifier 140 is a single phase full wave rectifier, voltage value of the discrete sinusoidal signal lower than the common mode voltage V_{CM} are converted to an equivalent voltage value of the discrete sinusoidal signal that is higher than the common mode voltage V_{CM}.

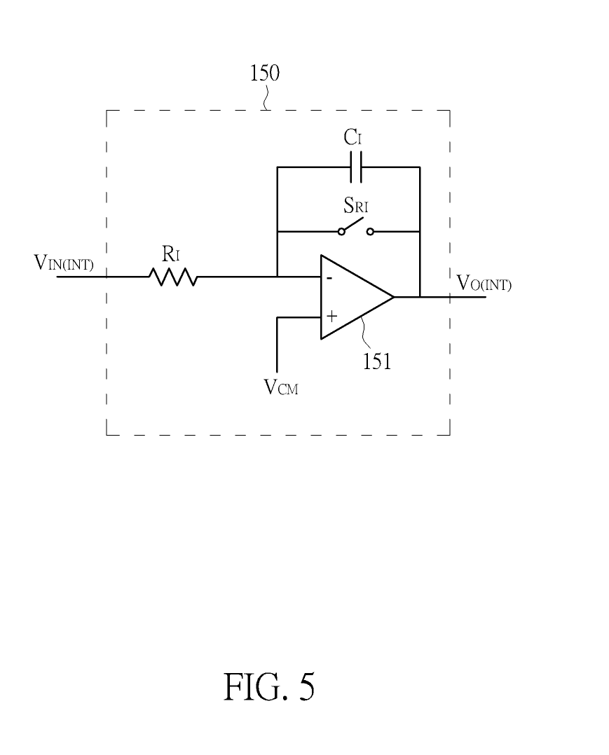

Please refer to FIG. 5. FIG. 5 illustrates a schematic diagram of the first embodiment of the integrator 150 according to the capacitor sensor circuit 100 shown in FIG. 1. The integrator 150 comprises an operational amplifier 151, a capacitor C_{I}, a resistor R_{I}, and a reset switch S_{RI}. A first terminal of the resistor R_{I} is coupled to the input terminal V_{IN(INT)} of the integrator 150 and the output terminal V_{O(REC)} of the rectifier 140. A second terminal of the resistor R_{I} is coupled to a negative input terminal of the operational amplifier 151. A positive input terminal of the operational amplifier 151 is coupled to the common mode voltage V. The output terminal of the operational amplifier 151 is coupled to the output terminal V_{O(INT)} of the integrator 150. A first terminal of the capacitor C_{I} is coupled to the second terminal of the resistor R_{I}. A second terminal of the capacitor C_{I} is coupled to the output terminal of the operational amplifier 151. A first terminal of the reset switch S_{RI} is coupled to the second terminal of the resistor R_{I}. A second terminal of the reset switch S_{RI} is coupled to the output terminal of the operational amplifier 151. A control terminal of the reset switch S_{RI} receives a reset signal. The output signal from the rectifier 140 is taken as an input signal to the integrator 150.

The integrator 150 shown in FIG. 5 is based around the operational amplifier 151. The integrator 150 performs a mathematical operation of integration with respect to time. The output signal of the integrator 150 is proportional to the input signal of the integrator 150 over time. The integrator 150 operates by passing a current that charges or discharges the capacitor CI over time. The common mode voltage VCM is a virtual ground. A current according to the resistor RI and the input signal of the integrator 150 is used to charge or discharge the capacitor CI. Because the resistor RI and capacitor CI are coupled to the virtual ground, the integrator 150 will perform a linear integration. For improving the accuracy or the integrator 150, the reset switch SRI is used. The reset switch SRI shall allow the integrator 150 to reset to zero according to a reset signal. A rule of operational amplifier circuit design states that there must always be a DC feedback path to the inverting input or operational amplifier output will go to rail. The general problem with an integrator circuit without reset is that an input offset current of an operational amplifier will be integrated by a capacitor to be a large output voltage, and eventually drive the operational amplifier output into saturation. The reset has the effect of discharging the capacitor CI and thereby resetting the integrator 150 and remove effect from the input offset current.

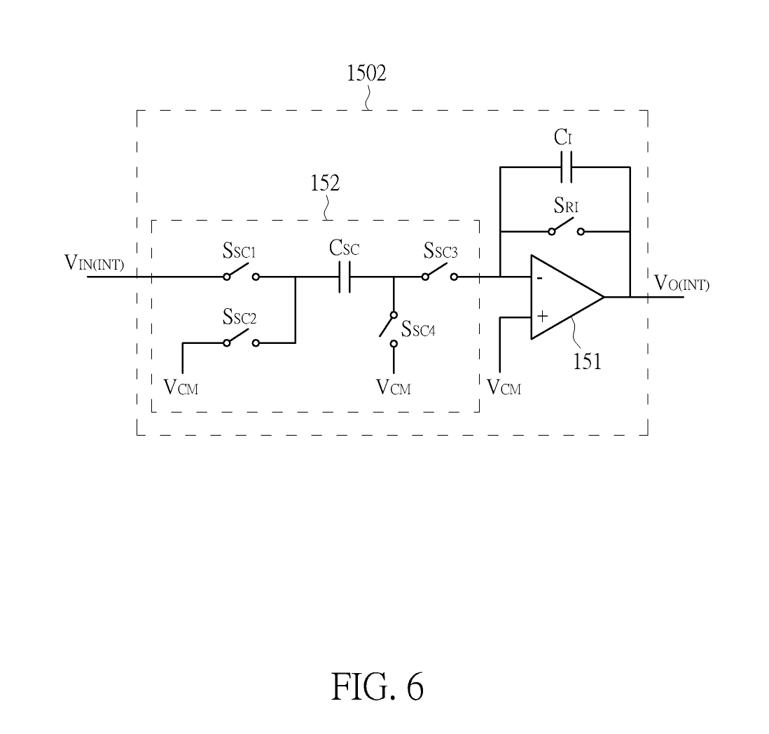

Please refer to FIG. 6. FIG. 6 illustrates a schematic diagram of the second embodiment of the integrator 1502 according to the capacitor sensor circuit 100 shown in FIG. 1. The integrator 150 of the capacitor sensor circuit 100 can be replaced with the integrator 1502. The integrator 1502 comprises the operational amplifier 151, a capacitor C_{I}, a reset switch S_{RI}, a switch capacitor circuit 152. A first terminal of the capacitor C_{I} is coupled to the negative input terminal of the operational amplifier 151. A second terminal of the capacitor C_{I} is coupled to the output terminal of the operational amplifier 151. A positive input terminal of the operational amplifier 151 is coupled to the common mode voltage V_{CM}. The output terminal of the operational amplifier 151 is coupled to the output terminal of V_{O(INT)} the integrator 1502. A first terminal of the reset switch S_{RI} is coupled to the negative input terminal of the operational amplifier 151. A second terminal of the reset switch S_{RI} is coupled to the output terminal of the operational amplifier 151. A control terminal of the reset switch S_{RI} receives a reset signal. A first terminal of the switch capacitor circuit 152 is coupled to the input terminal V_{IN(INT)} of the integrator 150. A second terminal of the switch capacitor circuit 152 is coupled to the negative input terminal of the operational amplifier 151.

The switch capacitor circuit 152 comprises a capacitor C_{SC}, a first switch S_{SC1}, a second switch S_{SC2}, a third switch S_{SC3}, and a fourth switch S_{SC4}. A first terminal of the first switch S_{SC1} is coupled to the first terminal of the switch capacitor circuit 152. A second terminal of the first switch S_{SC1} is coupled to a first terminal of the capacitor C_{SC}. A control terminal of the first switch S_{SC1} is coupled to a clock line clk. A first terminal of the second switch S_{SC2} is coupled to the common mode voltage V. A second terminal of the second switch is coupled to the first terminal of the capacitor C_{SC}. A control terminal of the second switch S_{SC2} is coupled to a clock line bar clkb. A first terminal of the third switch S_{SC3} is coupled to a second terminal of the capacitor C_{SC}. A second terminal of the third switch S_{SC3} is coupled to the second terminal of the switch capacitor circuit 152. A control terminal of the third switch S_{SC3} is coupled to the clock line bar clkb. A first terminal of the fourth switch S_{SC4} is coupled to the second terminal of the capacitor C_{SC}. A second terminal of fourth switch S_{SC4} is coupled to the common mode voltage V. A control terminal of the fourth switch S_{SC4} is coupled to the clock line clk. Note that signal from the clock line bar clkb may be inverted signal of signal coming from the clock line clk.

The integrator 1502 shown in FIG. 6 operates similarly to the integrator 150 shown in FIG. 5 with the resistor R_{I} replaced with the switch capacitor circuit 152. The operation of an integrator circuit and a switch capacitor circuit has been discussed in paragraphs above. Therefore the integrator 150 shown in FIG. 6 is not further described for brevity.

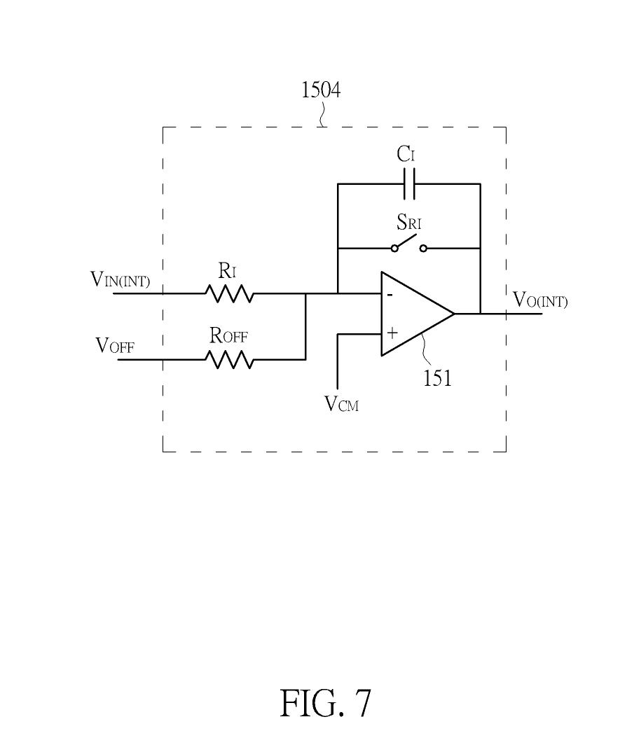

A third embodiment of the integrator 1504 shown in FIG. 5 may have an offset resistor R_{off} added to the integrator 150. Please refer to FIG. 7. FIG. 7 illustrates a schematic diagram of the third embodiment of the integrator 1504 according to the capacitor sensor circuit 100 shown in FIG. 1. The integrator 150 of the capacitor sensor circuit 100 can be replaced with the integrator 1504. A first terminal of the offset resistor R_{off} is coupled to an offset voltage V_{off}. A second terminal of the offset resistor R_{off} is coupled to the negative input terminal of the operational amplifier 151. The offset voltage V_{off} may be generated using a digital to analog converter. The removal of an offset voltage by the integrator 150 will allow the capacitor sensor circuit 100 to eliminate the effect of the mutual capacitor C_{M} from an output signal of the integrator 150 which is an input signal of the analog to digital converter 160. The removal of offset caused by the mutual capacitor C_{M} will allow the analog to digital converter 160 to measure an output signal that is directly proportional to capacitance of the finger capacitor C_{F}. Removal of the offset voltage V_{off} will prevent the operational amplifier 151 from reaching an overload state during operation.

The analog to digital converter 160 may be any type of analog to digital converter. The input terminal of the analog to digital converter 160 is coupled to the output terminal V_{O(INT)} of the integrator 150. A digital code shall be outputted at an output terminal of the analog to digital converter 160. The output signal of the integrator 150 is taken as the input signal of the analog to digital converter 160. The input signal is converted to the digital code outputted by the analog to digital converter 160 having a value proportional to the equivalent capacitance of the capacitor sensor 110. When removal of offset is performed by the integrator 150, the analog to digital converter 160 shall convert the input signal to the digital code outputted by the analog to digital converter 160 having a value proportional to capacitance of the finger capacitor C_{F} of the capacitor sensor 110.

The capacitor sensor circuit 100 takes a transmission signal from the transmitter node Tx and amplifies it according to the equivalent capacitance of the capacitor sensor 110 using the transimpedance amplifier 120. An amplified transmission signal is then inputted into the filter module 130. The filter module 130 filters out unwanted noise from the amplified transmission signal and convert the amplified transmission signal to a discrete sinusoidal signal. The discrete sinusoidal signal is then taken by the rectifier 140 as an input signal. The rectifier 140 then converts the discrete sinusoidal signal into a positive polarity discrete signal having plurality of voltage values corresponding to the discrete sinusoidal signal that is greater than the common mode voltage V. The rectifier 140 may be a half wave rectifier that only allow parts of the discrete sinusoidal signal having value greater than the common mode voltage V_{CM} to pass and blocks the other parts of the discrete sinusoidal signal. The rectifier 140 may be a full wave rectifier that passes parts of the discrete sinusoidal signal having value greater than the common mode voltage V_{CM} to the output and converts remaining parts of the discrete sinusoidal signal to a value higher than the common mode voltage V_{CM} and proportional to original value in the discrete sinusoidal signal. The positive polarity discrete signal is taken by the integrator 150 as an input signal. Integration of the positive polarity discrete signal is performed with respect to time creating an integrated signal. The integrator 150 may also be used for removing the offset voltage V_{off} corresponding to the mutual capacitor C_{M} of the capacitor sensor 110 to prevent occurrence of overloading. The integrated signal from the integrator 150 is taken as an input signal by the analog to digital converter 160. The analog to digital converter 160 converts the integrated signal to a digital code that reflects the change in the equivalent capacitance of the capacitor sensor 110.

The present invention discloses a capacitor sensor circuit 100 that is used for applications such as touch panels for mobile devices. The capacitor sensor circuit 100 includes a rectifier 140 and an integrator 150 that is used for preprocessing of a transmission signal. Since the transmission signal has been preprocessed and has passed through an integrator, a low speed analog to digital converter can be used by the capacitor sensor circuit 100 to generate a digital code that is proportional to the equivalent capacitance of a capacitor sensor 110 indicating a control command from a user to a touch panel of a mobile device. The low speed analog to digital converter will save in manufacturing cost since they have a simple circuitry compared to a high speed analog to digital converter. Hence, the low speed analog to digital converter requires less die area for fabrication than a high speed analog to digital converter. And the low speed analog to digital converter also have lower power consumption due to the simple circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor sensor circuit comprising:
a transimpedance amplifier, comprising:
an operational amplifier, having a negative input terminal coupled to a receiver node, a positive input terminal coupled to a reference voltage, and an output terminal coupled to an output terminal of the transimpedance amplifier; and
a capacitor, having a first terminal coupled to the receiver node and a second terminal coupled to the output terminal of the operational amplifier;
a filter module, having an input terminal coupled to the output terminal of the transimpedance amplifier and an output terminal;
a rectifier, having an input terminal coupled to the output terminal of the filter module and an output terminal;
an integrator, having an input terminal coupled to the output terminal of the rectifier and an output terminal; and
an analog to digital converter, having an input terminal coupled to the output terminal of the integrator and an output terminal.

2. The capacitor sensor circuit in claim 1, further comprising:
a capacitor sensor, comprising:
a sensing capacitor, having a first terminal coupled to a transmitter node and a second terminal coupled to the receiver node; and
a mutual capacitor, having a first terminal coupled to the transmitter node and a second terminal coupled to the receiver node.

3. The capacitor sensor circuit in claim 1, wherein the filter module comprises:
an anti-aliasing low pass filter, having an input terminal coupled to the input terminal of the filter module and an output terminal; and
a switch capacitor bandpass filter, having an input terminal coupled to the output terminal of the anti-aliasing low pass filter and an output terminal coupled to the output terminal of the filter module.

4. The capacitor sensor circuit in claim 1, wherein the filter module further comprises:
an anti-aliasing low pass filter, having an input terminal coupled to the input terminal of the filter module and an output terminal; and
a sample and hold circuit, having an input terminal coupled to the output terminal of the anti-aliasing low pass filter and an output terminal coupled to the output terminal of the filter module.

5. The capacitor sensor circuit in claim 1, wherein the filter module further comprises:
an anti-aliasing low pass filter, having an input terminal coupled to the input terminal of the filter module and an output terminal; and
a switch capacitor high pass filter, having an input terminal coupled to the output terminal of the anti-aliasing low pass filter and an output terminal coupled to the output terminal of the filter module.

6. The capacitor sensor circuit in claim 1, wherein the filter module further comprises:
a band pass filter, having an input terminal coupled to the input terminal of the filter module and an output terminal; and
a sample and hold circuit, having an input terminal coupled to the output terminal of the anti-aliasing low pass filter and an output terminal coupled to the output terminal of the filter module.

7. The capacitor sensor circuit in claim 1, wherein the rectifier comprises:
an operational amplifier, having a positive input terminal coupled to the input terminal of the rectifier, a negative input terminal coupled to a common mode voltage, and an output terminal;
an inverter, having an input terminal coupled to the output terminal of the operational amplifier and an output terminal.
a first switch, having a first terminal coupled to the common mode voltage, a second terminal coupled to the output terminal of the rectifier, and a third terminal coupled to the output terminal of the inverter; and
a second switch, having a first terminal coupled to the positive terminal of the operational amplifier, a second terminal coupled to the output terminal of the rectifier, and a third terminal coupled to the output terminal of the operational amplifier.

8. The capacitor sensor circuit in claim 1, wherein the integrator circuit comprises:
a resistor, having a first terminal coupled to the input terminal of the integrator, and a second terminal;
an operational amplifier, having a negative terminal coupled to the second terminal of the resistor, a positive terminal coupled to the common mode voltage, and an output terminal coupled to the output of the integrator;
a capacitor, having a first terminal couple to the negative terminal of the operational amplifier, and a second terminal coupled to the output terminal of the integrator;
a reset switch, having a first terminal couple to the negative terminal of the operational amplifier, a second terminal coupled to the output terminal of the integrator, and a third terminal coupled to a reset.

9. The capacitor sensor circuit in claim 8, wherein the integrator further comprises:
a switch capacitor circuit, having a first terminal coupled to the input terminal of the integrator, and a second terminal coupled to the negative terminal of the operational amplifier, the switch capacitor circuit comprising:
a first switch, having a first terminal coupled to the input terminal of the integrator, a second terminal, and a third terminal coupled to a clock line;
a second switch, having a first terminal coupled to the second terminal of the first switch, a second terminal coupled to the common mode voltage, and a third terminal coupled to a clock line bar;
a capacitor, having a first terminal coupled to the second terminal of the first switch and a second terminal;
a third switch, having a first terminal coupled to the second terminal of the capacitor, a second terminal coupled to the negative terminal of the operational amplifier, and a third terminal coupled to the clock line bar; and
a fourth switch, having a first terminal coupled to the first terminal of the third switch, a second terminal coupled to the common mode voltage, and a third terminal coupled to a clock line.

10. The capacitor sensor circuit in claim 8, wherein the integrator further comprises:
an offset resistor, having a first terminal coupled to an offset cancellation voltage and a second terminal coupled to the negative input terminal of the operational amplifier.
